(19) United States
(12) Patent Application Publication
(10) Pub. No.: US 2003/0049890 A1
(43) Pub. Date: Mar. 13, 2003

(54) Method for depaositing a leading wire layer of the semiconductor

(75) Inventors: Chong-Shyeng Liao, Taipei (TW); Matthew Tsai, Taipei (TW); Yu-Ting Lai, Jia-i (TW)

Correspondence Address: LOWE HAUPTMAN GILMAN, & BERNER, LLP, 1700 Diagonal Road, Suite 310, Alexandria, VA, 22314, US

(73) Assignee: UNITED MICROELECTRONICS CORP.

(21) Appl. No.: 09/945,649

(22) Filed: Sep. 5, 2001

(51) Int. Cl. H01L 21/44

(52) U.S. Cl. 438/123

(57) ABSTRACT

First of all, a semiconductor substrate that has a dielectric layer thereon is provided. Then a liner layer is deposited on the dielectric layer. Next, perform a heating process to rise the temperature of the semiconductor substrate, the dielectric layer and the liner layer until a predetermined temperature. Afterward, keep the predetermined temperature, and then a metal conducting layer is deposited on the liner layer by way of using the in-situ method at the predetermined temperature. Subsequently, terminate the heating process, and then an anti-reflection coating (ARC) layer is formed on the metal conducting layer by way of using the in-situ method.

### BACKGROUND OF THE INVENTION

1. Field of the Invention

The present invention relates generally to a method for forming a layer of leading wire in the semiconductor, and in particular to a method for depositing an aluminum layer.

2. Description of the Prior Art

As semiconductor devices, such as Metal-Oxide-Semiconductor devices, become highly integrated the area occupied by the device shrinks, as well as the design rule. With advances in the semiconductor technology, the dimensions of the integrated circuit (IC) devices have shrunk to the deep sub-micron range. When the semiconductor device continuously shrinks to the deep sub-micron region, some problems described below are incurred due to the scaling down process.

When semiconductor devices of integrated circuits (IC) become highly integrated, the surface of the chips can not be supplied with enough area to make the interconnects. For matching the requirement of interconnects increase with Complementary Metal-Oxide-Semiconductor (CMOS) devices shrinks, many designs of the integrated circuit have to use dual damascene method. Moreover, it is using the three-dimensional structure of multi-level interconnects at present in the deep sub-micron region, and inter-metal dielectric (IMD) as the dielectric material which is to be used to separate from each of the interconnects. A conducting wire which connects between the upper and the lower metal layers is called the via plug in semiconductor industry. In general, if an opening which forms in the dielectric layer exposure to devices of the substrate in the interconnects, it is called a via. Therefore, the upper and the lower metal layers are electrical connected to each other by way of the metal plug in the connect hole or via hole.

In general, after forming the contact windows and the via holes, a metal conducting wire is deposited over all of the contact windows and via holes to connect each of the metal plugs. The metal conducting wire is usually aluminum, and that the deposition of the metal conducting wire is used the physical vapor deposition (PVD). Conventional physical vapor deposition (PVD) for forming the aluminum layer is an aluminum process with two steps: the first step is that a nucleating layer of aluminum is deposited on a wafer, and then the second step is that the wafer is located into the chamber to heat and perform a deposition of aluminum. There are 0.5% content of copper in the material of aluminum. Because of the temperature of the process situation is increased by degrees from low temperature to high temperature about 300° C., the conventional deposition process with two step causes phase transformation between aluminum and copper, so that the aluminiferous copper, such as CuAl₂, is separated out. Nevertheless, the aluminiferous copper is difficult to remove during the follow-up etching process, and that will result in the metal-bridge phenomenon. Especially, in deep sub-micron technology, the critical dimension of the metal is more and more small and the metal-bridge phenomenon is more serious, so that the performance, quality and yield of the devices worsens.

On the other hand, a liner layer is formed before depositing the metal conducting wire, and an anti-reflection coating (ARC) layer is formed after depositing the metal conducting wire. In general, the liner layer and the anti-reflection coating (ARC) layer consist of TiN/Ti. Conventional forming the liner layer and the anti-reflection coating (ARC) layer both utilize the ex-situ method, that is, the reactive situation has to be changed to deposit the metal conducting ware after forming the liner layer, and then the reactive situation has to be changed again to form the anti-reflection coating (ARC) layer. Furthermore, the conventional method for forming the Ti layer of the liner layer utilizes the ion metal plasma process (IMP), and the conventional method for forming the TiN layer of the liner layer utilizes the high power plasma process (HPP) hence, the process situation of Ti is different from the process situation of TiN. Moreover, conventional Ti layer of the anti-reflection coating (ARC) layer is formed without controlling temperature, and conventional TiN layer of the anti-reflection coating (ARC) layer is formed by controlling the temperature about 300° C., hence, the process situation of Ti is different from the process situation of TiN. Therefore, conventional method for forming the liner layer and the anti-reflection coating (ARC) layer have to utilize ex-situ, so as to perform the reaction. As discussed above, the conventional process is easy to pollute the wafer to affect the quality of the wafer, and that the process cycle time is always increased, so as to waste the process cost.

In accordance with the above description, a new and improved method for forming a metal conducting layer is therefore necessary so as to raise the yield and quality of the follow-up process.

### SUMMARY OF THE INVENTION

In accordance with the present invention, a method is provided for forming a metal conducting layer that substantially overcomes the drawbacks of the above mentioned problems that arise from conventional methods.

Accordingly, it is a main object of the present invention to provide a method for forming a metal conducting layer. This invention can utilize a depositing process with one step to form the metal conducting ware, so as to avoid the metal-bridge effect. Furthermore, the depositing process with one step in the present invention is performed by way of using a preheating method, so as to prevent the metal compound that is hard to be removed from separating during the deposition of the metal conducting layer, whereby the semiconductor devices with small critical dimension can be formed, and the process can be simplified. Therefore, the present invention is appropriate for deep sub-micron technology in providing semiconductor devices.

Another object of the present invention is to provide a method for forming a metal conducting layer. This invention can utilize the in-situ process to form a liner layer, metal conducting layer and the anti-reflection coating (ARC) layer, so as to avoid polluting the wafer. Moreover, the present invention also can decrease the process cycle time, so as to raise the performance, quality and yield of the devices. Therefore, the present invention makes cost reductions that correspond to economic effect and appropriate for the utilization of the industry.

In accordance with the present invention, a new process for forming a metal conducting layer is disclosed. First of all, a semiconductor substrate that has a dielectric layer thereon is provided. Then a liner layer is deposited on the dielectric layer. Next, perform a cheating process to rise the temperature of the semiconductor substrate, the dielectric layer and the liner layer until a predetermined temperature. Afterward, keep the predetermined temperature, and then a metal conducting layer is deposited on the liner layer by way of using the in-situ method at the predetermined temperature. Subsequently, terminate the heating process, and then an anti-reflection coating (ARC) layer is formed on the metal conducting layer by way of using the in-situ method.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows cross-sectional views illustrative of various stages for forming the metal layer by way of using the preheating process and the in-situ process in accordance with the first embodiment of the present invention;

FIG. 2 shows cross-sectional views illustrative of various stages for forming the conducting layer with aluminum by way of using the preheating process and the in-situ process in accordance with the second embodiment of the present invention; and

FIG. 3A to FIG. 3E show cross-sectional views illustrative of various stages for performing the physical vapor deposition with aluminum by way of using the preheating process and the in-situ process to form the conducting layer with aluminum in accordance with the third embodiment of the present invention.

### DESCRIPTION OF THE PREFERRED EMBODIMENT

Preferred embodiments of the present invention will now be described in greater detail. Nevertheless, it should be recognized that the present invention can be practiced in a wide range of embodiments besides those explicitly described, and the scope of the present invention is expressly not limited except as specified in the accompanying claims.

As illustrated in FIG. 1, in the first embodiment of the present invention, a semiconductor substrate 100 is provided. Then a liner layer 110, such as TiN/Ti layer, is formed on the semiconductor substrate 100 at a first temperature, wherein the method for forming the liner layer 110 comprises a physical vapor deposition (PVD). Next, perform a heating process to rise the temperature of the semiconductor substrate 100 and the liner layer 110 until a second temperature. Afterward, keep the second temperature, and then a metal conducting layer 120, such as an aluminum layer, is formed on the liner layer 110 by way of using the in-situ method at the second temperature, wherein the method for forming the metal conducting layer 120 comprises a physical vapor deposition (PVD). Subsequently, terminate the heating process, and then an anti-reflection coating (ARC) layer 130, such as TiN/Ti layer, is formed on the metal conducting layer 120 by way of using the in-situ method, wherein the method for forming the anti-reflection coating (ARC) layer 130 comprises a physical vapor deposition (PVD).

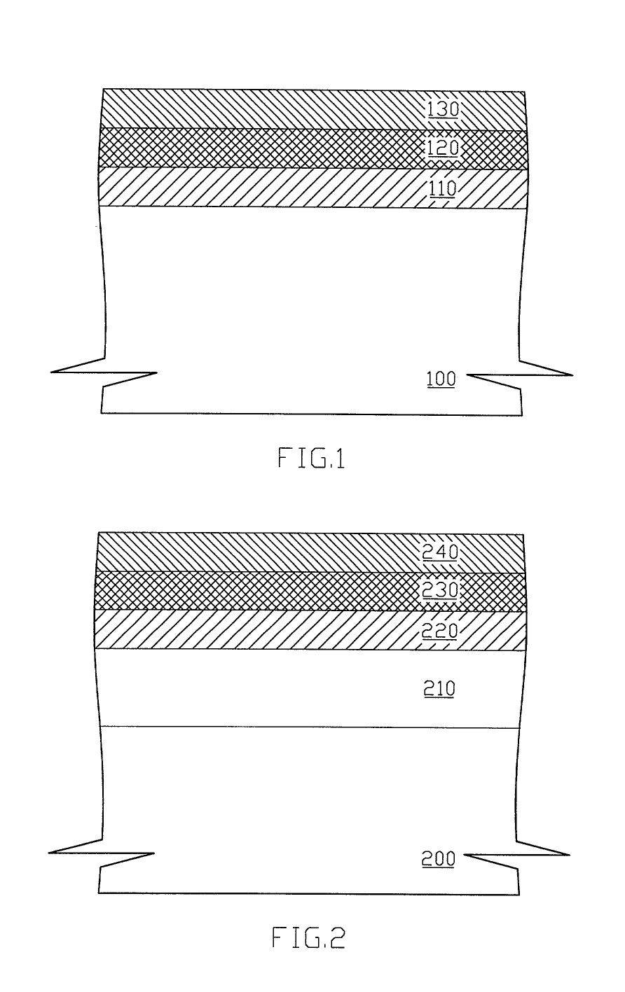

As illustrated in FIG. 2, in the second embodiment of the present invention, a semiconductor substrate 200 that has a dielectric layer 210 thereon is provided. Then a first TiN/Ti layer 220 as a liner layer is formed on the dielectric layer 210, wherein the method for forming the first TiN/Ti layer 220 comprises a physical vapor deposition (PVD). Next, perform a heating process to rise the temperature of the semiconductor substrate 200, the dielectric layer 210 and the first TiN/Ti layer 220 until a predetermined temperature, wherein the heating process comprises a backside argon heating process and the predetermined temperature comprises a range about 250° C. to 350° C. Afterward, keep the predetermined temperature, and then an aluminum layer 230 as a metal conducting layer is formed on the first TiN/Ti layer 220 by way of using the in-situ method at the predetermined temperature, wherein the method for forming the aluminum layer 230 comprises a physical vapor deposition (PVD). Subsequently, terminate the heating process, and then a second TiN/Ti layer 240 as an anti-reflection coating (ARC) layer is formed on the aluminum layer 230 by way of using the in-situ method, wherein the method for forming the second TiN/Ti layer 240 comprises a physical vapor deposition (PVD).

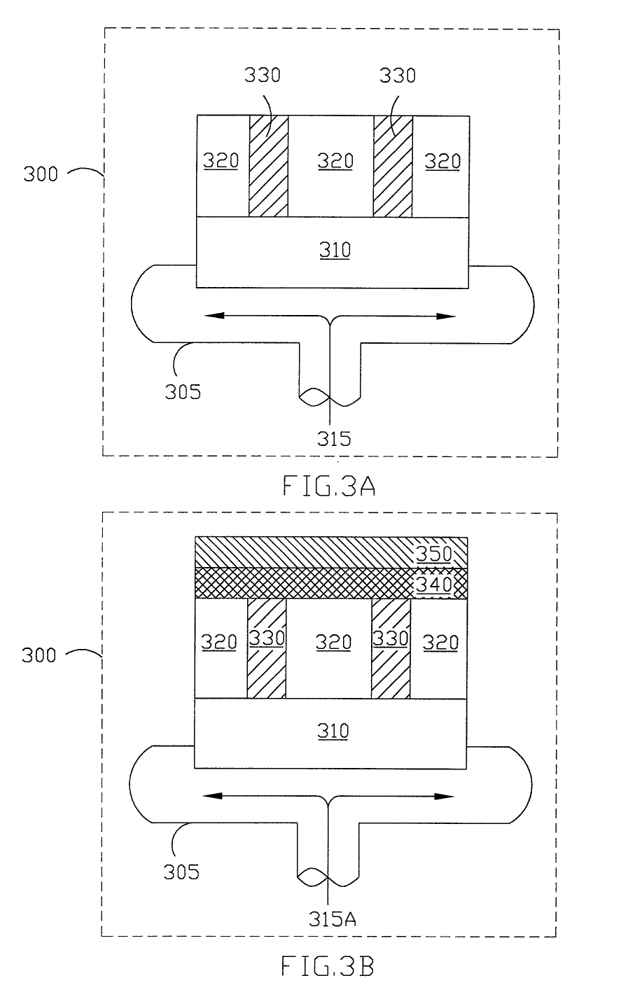

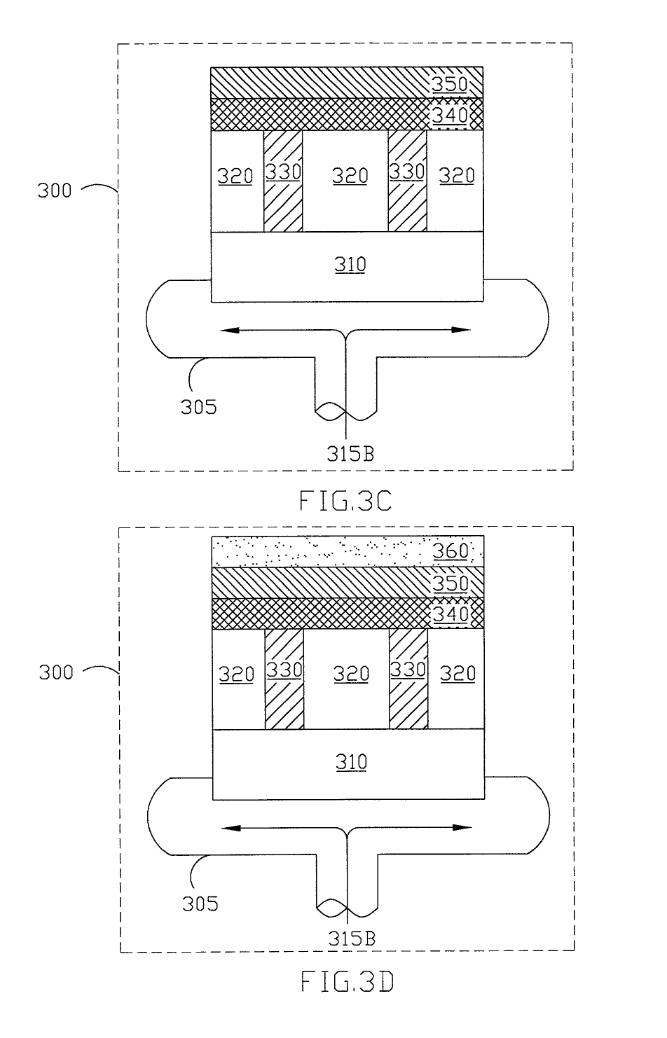

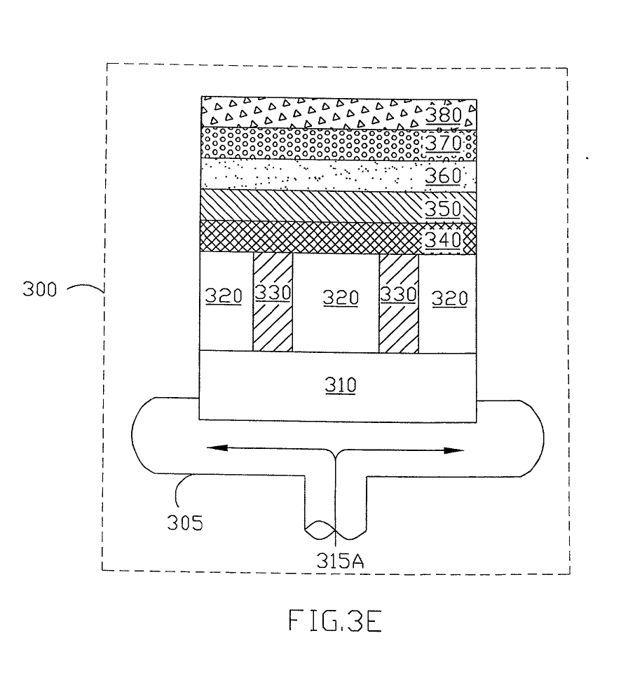

As illustrated in FIG. 3A and FIG. 3B, in the third embodiment of the present invention, a chamber 300 is provided. Then a semiconductor substrate 310 having a dielectric layer 320 is placed into the chamber 300, and the dielectric layer 320 has a plurality of metal plugs 330 therein, such as tungsten plugs, wherein the method for controlling the temperature of chamber 300 is a backside argon heating process, and follow-up processes are performed in this chamber 300 by way of using the in-situ method. Furthermore, the method for performing the backside argon heating process is to place the semiconductor substrate 310 on a process plate 305 in the chamber 300, and then an argon gas 315 is transported into the process plate 305 to conduct the calorific capacity of the argon gas 315 into the semiconductor substrate 310, so as to control the process temperature. A first titanium layer 340 is then formed on the dielectric layer 320 and the plurality of the metal plug 330 by way of using a first physical vapor deposition. Next, a first nitride titanium layer 350 is then formed on the first titanium layer 340 by way of using a first physical vapor deposition, wherein the process for forming the first titanium layer 340 and the first nitride titanium layer 350 are performed without controlling temperature in the chamber 300, that is, the argon gas 315A that is not heated is transported into the process plate 305.

As illustrated in FIG. 3C and FIG. 3E, in this embodiment, a preheating process is performed by way of using the argon gas 315B that has been heated, so as to arise the temperature of the semiconductor substrate 310, the dielectric layer 320, the plurality of metal plug 330, the first titanium layer 340 and the first nitride titanium layer 350 until the reactive temperature about 300° C. Afterward, keep the reactive temperature about 300° C. at a predetermined period, and then an aluminum layer 360 is formed on the first nitride titanium layer 350 by way of using a third physical vapor deposition, wherein the predetermined period is about 15 second to 25 second. Subsequently, the argon gas 315A that is not heated is transported into the process plate 305, so as to lower the temperature naturally. Then a second titanium layer 370 is formed on the aluminum layer 360 by way of using a fourth physical vapor deposition without controlling the reactive temperature. Finally, the argon gas 315A that is not heated is continuously transported into the process plate 305, and then a second nitride titanium layer 380 is formed on the second titanium layer 370 by way of using a fifth physical vapor deposition without controlling the reactive temperature.

In these embodiments of the present invention, as discussed above, this invention can utilize a depositing process with one step to form the metal conducting ware, so as to avoid the metal-bridge effect. Furthermore, the depositing process with one step in the present invention is to utilize a preheating method to rise the temperature to a predetermined temperature, so as to prevent the issue of the metal compound that is hard to remove is separated during the deposition of the metal conducting layer, whereby the semiconductor devices with small critical dimension can be formed, and the process can be simplified. Therefore, the present invention is appropriate for deep sub-micron technology in providing semiconductor devices. On the other hand, this invention can utilize the in-situ method to form a liner layer, a metal conducting layer and an anti-reflection coating (ARC) layer, so as to avoid polluting the wafer. Moreover, the present invention also can decrease the process cycle time, so as to raise the performance, quality and yield of the devices. Therefore, the present invention makes cost reductions that correspond to economic effect and appropriate for the utilization of the industry. Accordingly, the differences between this invention and conventional process are non-obviously as showed in following table:

| | Liner | | Metal | | |
|---|---|---|---|---|---|
| Item | layer | | layer | ARC | |
| Conventional | | | | | |
| depositing | | | | | |
| process with | | | | | |
| metal | | | | | |
| Forming layer | Ti | TiN | Al | Ti | TiN |
| process | IMP | HP | PVD | PVD | PVD |
| Temperature | ″ | ″ | ″ | none | ″ |
| control | | | | | |
| Process | Ex-situ | | | Ex-situ | |
| situation | | | | | |
| This invention | | | | | |
| for depositing | | | | | |
| process with metal | | | | | |
| Forming | Ti | TiN | Al | Ti | TiN |
| layer | | | | | |
| process | PVD | PVD | One step | PVD | PVD |
| | | | of PVD with | | |
| | | | preheating | | |
| | | | process | | |
| Temperature | none | none | One step | none | none |
| control | | | of PVD with | | |
| | | | preheating | | |
| | | | process | | |

| | | |
|---|---|---|
| Process | In-situ | In-situ |
| situation | | |

Of course, it is possible to apply the present invention to form the aluminum layer with the physical vapor depositing process, and to any process for forming the metal conducting layer in processing semiconductor devices. Also, this invention can be applied to avoid the metal bridge by way of using a preheating process concerning the physical vapor deposition with one step used for forming the aluminum layer has not been developed at present. The method of the present invention is the best process for forming the metal conducting layer compatible process for deep sub-micro process.

Obviously, many modifications and variations of the present invention are possible in light of the above teachings. It is therefore to be understood that within the scope of the appended claims, that the present invention may be practiced other than as specifically described herein.

Although the specific embodiments have been illustrated and described, it will be obvious to those skilled in the art that various modifications may be made without departing from what is intended to be limited solely by the appended claims.

What is claimed is:

1. A method for forming a metal layer, the method comprising:
providing a semiconductor substrate;
performing a preheating process to increase the temperature of said semiconductor substrate until a predetermined temperature and keeping said predetermined temperature; and
forming a metal layer on said semiconductor substrate at said predetermined temperature.

2. The method according to claim 1, wherein said metal layer comprises an aluminum layer.

3. The method according to claim 1, wherein the method for forming said metal layer comprises a physical vapor deposition.

4. A method for forming a metal layer, the method comprising:
providing a semiconductor substrate;
forming a liner layer on said semiconductor substrate at a first temperature;
performing a heating process to increase said first temperature of said semiconductor substrate and said liner layer until a second temperature, and keeping said second temperature;
forming a metal conducting layer on said liner layer at said second temperature;
terminating said heating process; and
decreasing said second temperature to said first temperature and forming an anti-reflection coating layer on said metal layer.

5. The method according to claim 4, wherein said liner layer comprises a first TiN/Ti layer.

6. The method according to claim 5, wherein the method for forming said first TiN/Ti layer comprises an in-situ method.

7. The method according to claim 4, wherein the method for forming said liner layer comprises a physical vapor deposition.

8. The method according to claim 4, wherein said metal layer comprises an aluminum layer.

9. The method according to claim 4, wherein the method for forming said metal layer comprises a physical vapor deposition.

10. The method according to claim 4, wherein said anti-reflection coating layer comprises a second TiN/Ti layer.

11. The method according to claim 10, wherein the method for forming said second TiN/Ti layer comprises an in-situ method.

12. The method according to claim 4, wherein the method for forming said anti-reflection coating layer comprises a physical vapor deposition.

13. A method for forming a metal conducting layer, the method comprising:
providing a semiconductor substrate, wherein said semiconductor substrate has a dielectric layer thereon;
forming a first TiN/Ti layer on said dielectric layer;
performing a heating process to increase said semiconductor substrate, said dielectric layer and said first TiN/Ti layer until a predetermined temperature, and keeping said predetermined temperature;
forming an metal conducting layer on said first TiN/Ti layer by way of using an in-situ method at said predetermined temperature;
terminating said heating process; and
decreasing said predetermined temperature and forming a second TiN/Ti layer on said metal conducting layer.

14. The method according to claim 13, wherein the method for forming said first TiN/Ti layer comprises a physical vapor deposition.

15. The method according to claim 13, wherein said heating process comprises a backside argon heating process.

16. The method according to claim 13, wherein said predetermined temperature comprises a range about 250° C. to 350° C.

17. The method according to claim 13, wherein the method for forming said metal conducting layer comprises a physical vapor deposition.

18. The method according to claim 13, wherein said metal conducting layer comprises an aluminum layer.

19. The method according to claim 13, wherein the method for forming said second TiN/Ti layer comprises a physical vapor deposition.

20. A method for forming a metal conducting layer of a plurality of metal plugs, the method comprising:
providing a semiconductor substrate with a dielectric layer thereon, wherein said dielectric layer has said plurality of metal plugs therein;
forming a first titanium layer on said dielectric layer and said plurality of metal plugs;
forming a first nitride titanium layer on said first titanium layer by way of using an in-situ method;
performing a preheating process to increase said semiconductor substrate, said dielectric layer, said plurality of metal plugs, said first titanium layer and said first nitride titanium layer until a predetermined temperature, and keeping said predetermined temperature;
forming a metal conducting layer on said first nitride titanium layer by way of using said in-situ method at said predetermined temperature;
terminating said preheating process;
decreasing said predetermined temperature and forming a second titanium layer on said metal conducting layer; and
forming a second nitride titanium layer on said second titanium layer.

21. The method according to claim 20, wherein said plurality of metal plugs comprises tungsten plugs.

22. The method according to claim 20, wherein the method for forming said first titanium layer comprises a physical vapor deposition.

23. The method according to claim 20, wherein the method for forming said first nitride titanium layer comprises a physical vapor deposition.

24. The method according to claim 20, wherein said preheating process comprises a backside argon heating process.

25. The method according to claim 20, wherein said predetermined temperature comprises a range about 250° C. to 350° C.

26. The method according to claim 20, wherein the method for forming said metal conducting layer comprises a physical vapor deposition.

27. The method according to claim 20, wherein said metal conducting layer comprises an aluminum layer.

28. The method according to claim 20, wherein the method for forming said second titanium layer comprises a physical vapor deposition.

29. The method according to claim 20, wherein the method for forming said second nitride titanium layer comprises a physical vapor deposition.

30. A method for forming an aluminum conducting layer on a plurality of tungsten plugs, the method comprising:
providing a chamber with a process plate and a backside argon heating process;
providing a semiconductor substrate with a dielectric layer thereon, wherein said dielectric layer has said plurality of tungsten plugs therein, and placing said semiconductor substrate on said process plate of said chamber;
transporting a first argon gas with a first temperature into said process plate of said chamber;
forming a first titanium layer on said dielectric layer and said plurality of metal plugs by way of using a first physical vapor deposition at said first temperature of said process plate;
forming a first nitride titanium layer on said first titanium layer by way of using a second physical vapor deposition at said first temperature of said process plate;
performing a heating process by transporting a second argon gas with a second temperature into said process plate of said chamber, so as to increase said first temperature of said semiconductor substrate, said dielectric layer, said plurality of tungsten plugs, said first titanium layer and said first nitride titanium layer until said second temperature, and keeping said second temperature;
forming an aluminum layer on said first nitride titanium layer by way of using a third physical vapor deposition at said second temperature of said process plate;
transporting said first argon gas with said first temperature into said process plate to decrease said second temperature of said process plate to said first temperature, and forming a second titanium layer on said aluminum layer by way of using a fourth physical vapor deposition; and
forming a second nitride titanium layer on said second titanium layer by way of using a fifth physical vapor deposition at said first temperature of said process plate, so as to form said aluminum conducting layer on said plurality of tungsten plugs.

31. The method according to claim 30, wherein the method for forming said second temperature comprises a range about 250° C. to 350° C.
